(19) United States
(12) Patent Application Publication
(10) Pub. No.: US 2025/0240887 A1
(43) Pub. Date: Jul. 24, 2025

(54) CIRCUIT BOARD AND METHOD OF MANUFACTURING THE SAME

(71) Applicant: Unimicron Technology Corp., Taoyuan City (TW)

(72) Inventors: Chin-Sheng WANG, Taoyuan City (TW); Ra-Min TAIN, Taoyuan City (TW); Guang-Hwa MA, Taoyuan City (TW); Tzyy-Jang TSENG, Taoyuan City (TW); Cheng-Ta KO, Taoyuan City (TW); Pu-Ju LIN, Taoyuan City (TW)

(21) Appl. No.: 19/174,951

(22) Filed: Apr. 10, 2025

Related U.S. Application Data
(63) Continuation-in-part of application No. 18/668,275, filed on May 20, 2024.
Application No. 18/668,275 is a division of application No. 17/448,893, filed on Sep. 26, 2021, now Pat. No. 11,991,824.
Application No. 17/448,893 is a continuation-in-part of application No. 17/191,559, filed on Mar. 3, 2021, now Pat. No. 11,540,396.
(60) Provisional application No. 63/071,369, filed on Aug. 28, 2020.
(60) Provisional application No. 63/643,932, filed on May 8, 2024.
(60) Provisional application No. 63/658,882, filed on Jun. 12, 2024.

(30) Foreign Application Priority Data
Jan. 12, 2021 (TW) 110101060
Jul. 9, 2021 (TW) 110125380
Dec. 31, 2024 (TW) 113151809

(51) Int. Cl. H05K 1/11; H05K 1/03; H05K 3/00

(52) U.S. Cl. CPC H05K 1/115; H05K 1/0306; H05K 3/0067; H05K 3/0094

(57) ABSTRACT

A circuit board and a method of manufacturing the same are provided. The circuit board includes two circuit substrates and a conductive layer. The circuit substrates are stacked on each other, while each of the circuit substrates includes an insulation substrate and a conductive via which is disposed inside the insulation substrate. Two opposite sides of the insulation substrate are connected to each other through the conductive via. The conductive layer is disposed between the conductive vias, and the conductive vias are electrically connected to each other through the conductive layer which includes the nanoporous structure.

### RELATED APPLICATIONS

This application claims priority to U.S. Provisional Application Ser. No. 63/643,932 filed May 8, 2024, and No. 63/658,882 filed Jun. 12, 2024, and Taiwan Application Serial Number 113151809, filed Dec. 31, 2024. This application is also a Continuation-in-Part of U.S. application Ser. No. 18/668,275, filed on May 20, 2024, which is a Divisional Application of U.S. application Ser. No. 17/448,893 filed on Sep. 26, 2021, which claims priority to Taiwan Application Serial Number 110125380, filed on Jul. 9, 2021 and is also a Continuation-in-part of U.S. application Ser. No. 17/191,559, filed on Mar. 3, 2021, which claims priority to U.S. Provisional Application Ser. No. 63/071,369 filed Aug. 28, 2020, and Taiwan Application Serial Number 110101060, filed Jan. 12, 2021. All of the disclosures of which are incorporated herein by reference in their entireties.

### BACKGROUND

### Technical Field

The present disclosure relates to a circuit board and a method of manufacturing of the same.

### Description of Related Art

In recent years, the applications of circuit boards using glass substrates have gradually increased. Due to the material characteristics of the glass substrates, the aspect ratio of the conductive vias disposed in the glass substrates is difficult to be increased. In other words, the depth of the conductive vias is limited by the machining technology of the glass substrates. That is, when the thickness of the glass substrate is thicker, the width of the conductive via should be wider, which is disadvantage for expanding the applications of circuit boards using glass substrates. On the other hand, if the aspect ratio of the conductive vias in the glass substrates is increased by laminating multiple layers of circuit substrates, the electrical properties and mechanical reliability of the conductive vias will be affected.

### SUMMARY

Accordingly, at least one embodiment of the disclosure is to provide a circuit board.

At least one embodiment of the disclosure is to provide a method of manufacturing the aforementioned circuit board.

At least one embodiment of the disclosure provides a circuit board including two first circuit substrates stacked on each other and a first conductive layer. Each of the first circuit substrates includes an insulation substrate and a first conductive via disposed inside the insulation substrate. The first conductive via is connected to two opposite sides of the insulation substrate. The first conductive layer is disposed between the first conductive vias, and the first conductive vias are electrically connected to each other through the first conductive layer. The first conductive layer includes nanoporous structures.

At least in one embodiment of the disclosure, the circuit board further includes an insulation layer disposed between the first circuit substrates and surrounding a perimeter of the first conductive layer.

At least in one embodiment of the disclosure, the circuit board further includes a conductive pillar disposed on the first conductive layer and located between one of the first conductive vias and the first conductive layer. The one of the first conductive vias is electrically connected to the first conductive layer through the conductive pillar.

At least in one embodiment of the disclosure, each of the first conductive vias includes two pads disposed on two opposite end surfaces of the first conductive via. The first conductive via is connected to the first conductive layer through one of the pads.

At least in one embodiment of the disclosure, at least one of the insulation substrates is a glass substrate.

At least in one embodiment of the disclosure, the circuit board further includes a second circuit substrate disposed between the first circuit substrates and a second conductive layer disposed on the second conductive via. The second circuit substrate is located between one of the first circuit substrates and first conductive layer. The second circuit substrate includes a second conductive via connected to two opposite sides of the second circuit substrate and electrically connected to the first circuit substrates, and the second conductive via is connected to one of the first conductive vias through the first conductive layer. The second conductive layer is located between the first conductive layer and the second conductive layer, and the second conductive via is connected to another one of the first conductive vias through the second conductive layer. The second conductive layer includes the nanoporous structure.

At least in one embodiment of the disclosure, a ratio of a thickness of the insulation substrate to a width of the first conductive via is between 1 and 20.

At least in one embodiment of the disclosure, a thickness of the insulation substrate is between 50 μm and 4000 μm.

At least in one embodiment of the disclosure, a width of the first conductive via is between 50 μm and 200 μm.

At least in one embodiment of the disclosure, the nanoporous structure includes a plurality of pores, and a diameter of the plurality of pores is between 1 nm and 10 μm.

At least one embodiment of the disclosure provides a method for manufacturing a circuit board including forming at least two circuit substrates, and each of the circuit substrates includes an insulation substrate and a conductive via disposed inside the insulation substrate. The conducive via is connected to two opposite sides of the insulation substrate. The method includes forming a plurality of nanowires on at least one end surface of one of the conductive vias, and the plurality of nanowires extend to a direction away from the at least one end surface. The method includes laminating the circuit substrates after the plurality of nanowires are formed. The nanowires located at the one of the conductive vias are aligned to another one of the conductive vias, and the plurality of nanowires are located between the conductive vias, and a conductive layer is formed from the plurality of nanowires. The conductive vias are electrically connected to each other through the conductive layer, and the conductive layer includes a nanoporous structure.

At least in one embodiment of the disclosure, the method further includes forming an insulation layer on the circuit substrates after the circuit substrates are laminated, and the insulation layer is located between the circuit substrates. The insulation layer surrounds a perimeter of the conductive layer.

At least in one embodiment of the disclosure, the method further includes disposing an insulation material on the plurality of nanowires before the circuit substrates are laminated. The insulation material covers the end surface of the one of the conductive vias, and the insulation material encapsulates the plurality of nanowires. The method further includes adhering another one of the conductive vias to the plurality of nanowires, and the another one of the conductive vias touches the plurality of nanowires directly.

At least in one embodiment of the disclosure, at least one of the insulation substrates is a glass substrate.

A least in one embodiment of the disclosure, the nanoporous structure includes a plurality of pores, and a diameter of the plurality of pores is between 1 nm and 10 μm.

According to the aforementioned embodiments, the nanowires are disposed on the laminating interfaces between circuit substrates so as to form the conductive layer including the nanoporous structure between the conductive vias which are connected to one another. As a result, the bonding strength between conductive vias of each circuit substrate may increase without affecting the electrical connections, so that the reliability of the circuit board increases. Therefore, when the insulation substrates of the circuit board are glass substrates, the aspect ratio of the conductive vias in the glass substrates may be increased by stacking multiple layers of the circuit substrates, thereby expanding the applications of the circuit board.

### BRIEF DESCRIPTION OF THE DRAWINGS

To illustrate more clearly the aforementioned and the other features, merits, and embodiments of the present disclosure, the description of the accompanying figures are as follows:

FIG. 1 illustrates a cross-sectional view of a circuit board in accordance with at least one embodiment of the present disclosure.

FIG. 2 illustrates a cross-sectional view of a circuit board in accordance with at least one embodiment of the present disclosure.

FIG. 3 illustrates a cross-sectional view of a circuit board in accordance with at least one embodiment of the present disclosure.

FIG. 4A to FIG. 4E illustrate cross-sectional views of a method of manufacturing a circuit board in accordance with at least one embodiment of the present disclosure.

FIG. 5 illustrates a locally top view of a circuit board in accordance with at least one embodiment of the present disclosure.

FIG. 6 illustrates a cross-sectional view of a method of manufacturing a circuit board in accordance with at least one embodiment of the present disclosure.

FIG. 7 illustrates a cross-sectional view of a circuit board in accordance with at least one embodiment of the present disclosure.

### DETAILED DESCRIPTION

In the following description, the dimensions (such as lengths, widths and thicknesses) of components (such as layers, films, substrates and regions) in the drawings are enlarged not-to-scale, and the number of components may be reduced in order to clarify the technical features of the disclosure. Therefore, the following illustrations and explanations are not limited to the number of components, the number of components, the dimensions and the shapes of components, and the deviation of size and shape caused by the practical procedures or tolerances are included. For example, a flat surface shown in drawings may have rough and/or non-linear features, while angles shown in drawings may be circular. As a result, the drawings of components shown in the disclosure are mainly for illustration and not intended to accurately depict the real shapes of the components, nor are intended to limit the scope of the claimed content of the disclosure.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. In addition, the number or range of numbers encompasses a reasonable range including the number described, such as within +/−30%, +/−20%, +/−10% or +/−5% of the number described, based on known manufacturing tolerances associated with manufacturing a feature having a characteristic associated with the number. The words of deviations such as “about,” “approximate,” “substantially,” and the like are chosen in accordance with the optical properties, etching properties, mechanical properties or other properties. The words of deviations used in the optical properties, etching properties, mechanical properties or other properties are not chosen with a single standard.

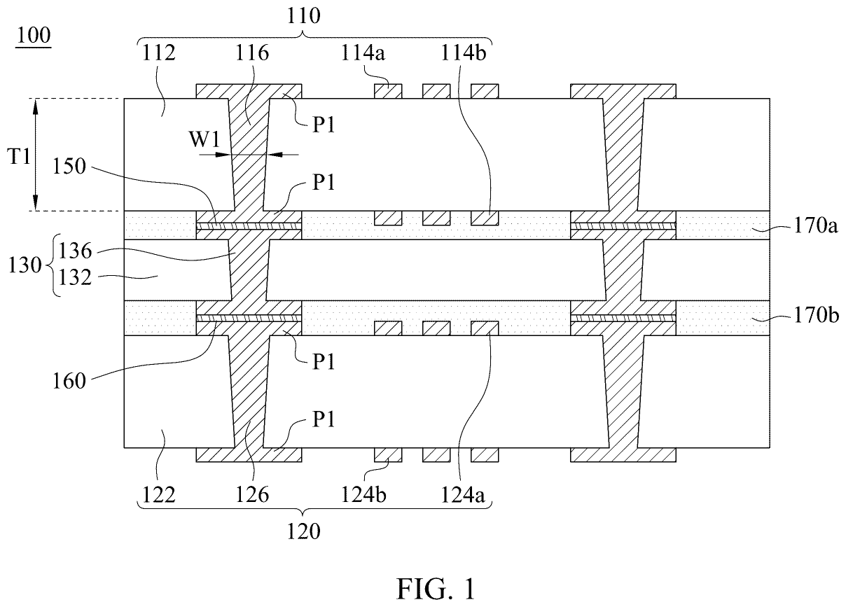

FIG. 1 illustrates a locally cross-sectional view of a circuit board 100 in accordance with at least one embodiment of the present disclosure. The circuit board 100 includes a circuit substrate 110 and a circuit substrate 120 which are stacked on each other and a conductive layer 150. The circuit substrate 110 includes an insulation substrate 112, a circuit layer 114a, a circuit layer 114b and a conductive via 116, where the insulation substrate 112 is disposed between the circuit layer 114a and the circuit layer 114b. The conductive via 116 is disposed inside the insulation substrate 112 and connected to two opposite sides of the insulation substrate 112. Specifically, the conductive via 116 passes the insulation substrate 112 through the circuit layer 114a and extends to the circuit layer 114b so as to be electrically connected to the circuit layer 114a and the circuit layer 114b.

In addition, the circuit substrate 120 includes an insulation substrate 122, a circuit layer 124a, a circuit layer 124b and a conductive via 126, where the insulation substrate 122 is disposed between the circuit layer 124a and the circuit layer 124b. The conductive via 126 is disposed inside the insulation substrate 122 and connected to two opposite sides of the insulation substrate 122. Specifically, the conductive via 126 passes the insulation substrate 122 through the circuit layer 124a and extends to the circuit layer 124b so as to be electrically connected to the circuit layer 124a and the circuit layer 124b.

The conductive layer 150 is disposed between the conductive via 116 and the conductive via 126, while the conductive via 116 and the conductive via 126 are electrically connected to each other through the conductive layer 150. Specifically, in the embodiment, the circuit board 100 further includes a circuit substrate 130 and another conductive layer 160. The circuit substrate 130 is disposed between the circuit substrate 110 and the circuit substrate 120, and the circuit substrate 130 is located between the circuit substrate 120 and the conductive layer 150. The circuit substrate 130 includes a conductive via 136 which is connected to two opposite sides of the circuit substrate 130 and electrically connected to the circuit substrate 110 and the circuit substrate 120 separately.

The conductive layer 160 is disposed on the conductive via 136, while the circuit substrate 130 is located between the conductive layer 150 and the conductive layer 160. According to the configuration, the conductive via 136 is able to be connected to the conductive via 116 through the conductive layer 150, while the conductive via 136 is able to be connected to the conductive via 126 through the conductive layer 160. That is, in the embodiment, the conductive via 116 and the conductive via 126 are electrically connected to each other through the conductive layer 150, the conductive via 136 and the conductive layer 160.

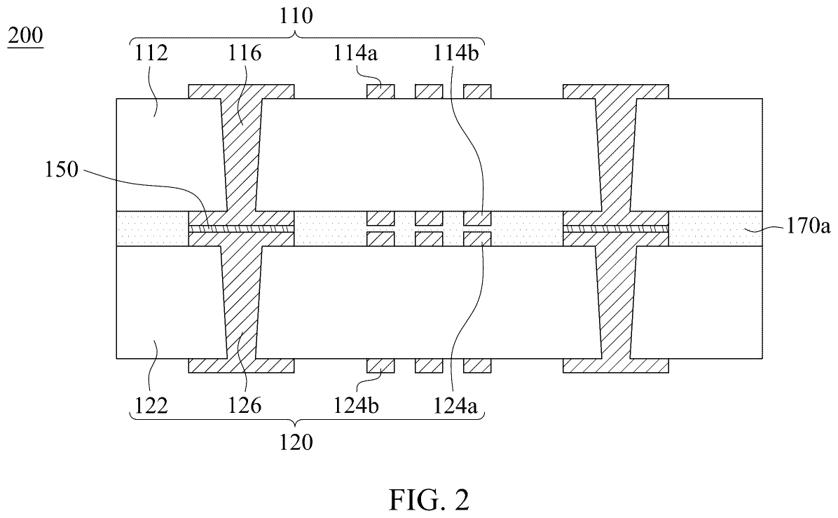

However, the disclosure is not limited to the embodiment. In other embodiment, the conductive via 116 may be electrically connected to the conductive via 126 barely through the conductive layer 150 (i.e., the conductive layer 150 directly touches the conductive via 116 and the conductive via 126 separately). For instance, referring to another embodiment in FIG. 2, a circuit board 200 is similar to the circuit board 100, that is, the circuit board 200 includes the circuit substrate 110, the circuit substrate 120 and the conductive layer 150. The difference between the circuit board 100 and the circuit board 200 is that the circuit board 200 excludes the circuit substrate 130 and the conductive layer 160, so that the conductive via 116 and the conductive via 126 are electrically connected to each other barely through the conductive layer 150.

The conductive layer 150 and the conductive layer 160 include a nanoporous structure, and the conductive layer 150 (and the conductive layer 160) may include conductive materials, such as metals (e.g., copper). For instance, the conductive layer 150 (and the conductive layer 160) may be a metal layer including a porous structure, while the diameter of a plurality of pores included in the porous structure is between 1 nm and 10 μm. It is worth mentioning, the conductivity of the nanoporous structure is around 5.96×10⁷ S/m. In other words, the conductivity of the conductive layer 150 (and the conductive layer 160) will not decrease due to the nanoporous distributed inside.

Referring to FIG. 1, the circuit board 100 further includes an insulation layer 170a and an insulation layer 170b. The insulation layer 170a and the insulation layer 170b are disposed between the circuit substrate 110 and the circuit substrate 120, while the perimeters of the conductive layer 150 and the conductive layer 160 are surrounded by the insulation layer 170a and the insulation layer 170b. Specifically, the insulation layer 170a is located between the circuit substrate 110 and the circuit substrate 130, and the insulation layer 170b is located between the circuit substrate 130 and the circuit substrate 120.

It is worth mentioning, each conductive via 116 (or each conductive via 126) includes two pads P1. The pads P1 are disposed on two opposite sides (not denoted) of the conductive via 116 (or the conductive via 126) separately. The conductive via 116 is connected to the conductive layer 150 through one of the pads P1, while the conductive via 126 is connected to the conductive layer 150 through one of the pads P1. Specifically, the conductive via 116 is directly connected to the conductive layer 150 through one of the pads P1, while the conductive via 126 is connected to the conductive layer 150 through one of the pads P1, the conductive layer 160 and the conductive via 136 in the embodiment.

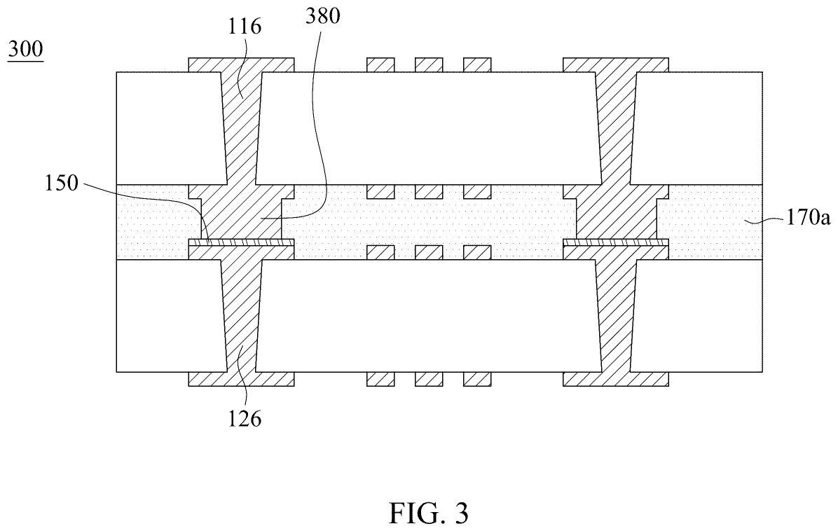

Referring to FIG. 3, a circuit board 300 in the embodiment is similar to the circuit board 200, that is, the circuit board 300 includes the circuit substrate 110, the circuit substrate 120 and the conductive layer 150 but excludes the circuit substrate 130 and the conductive layer 160. The difference between the circuit board 300 and the circuit board 200 is that the circuit board 300 further includes conductive pillars 380. The conductive pillars 380 are disposed on the conductive layer 150 and located between the conductive via 116 and the conductive layer 150. As a result, the conductive via 116 may be electrically connected to the conductive layer 150 through the conductive pillars 380. The conductive pillars 380 may include conductive materials, such as metals (e.g., copper).

It is worth mentioning, at least one of the insulation substrate 112 and the insulation substrate 122 is a glass substrate, and the materials of the glass substrate may include silicon, ceramic or sapphire. Take FIG. 1 and FIG. 2 as an example, both of the insulation substrate 112 and the insulation substrate 122 are glass substrates, but the disclosure is not limited to the embodiment. In other embodiments, only the insulation substrate 112 is a glass substrate, but the insulation substrate 122 is a substrate including other insulation materials, such as prepregs, Ajinomoto buildup films (ABF), Bismaleimide Triazine (BT) resins, photosensitive dielectrics (PID) or other B-stage polymers.

When the insulation substrate 112 is a glass substrate, the ratio of the thickness T1 of the insulation substrate 112 to the width W1 of the conductive via 116 is between 1 and 20. For instance, the thickness T1 of the insulation substrate 112 may be between 50 μm and 4000 μm, while the width W1 of the conductive via 116 may be between 50 μm and 200 μm.

In various embodiments of the disclosure, the number of the circuit substrates in the circuit board 100 is not limited to the aforementioned embodiments (i.e., is not limited to two or three circuit substrates). In other embodiments, the number of the circuit substrates in the circuit board 100 may be any integer more than two, such as five circuit substrates. Furthermore, although each circuit substrate in the aforementioned embodiments includes two conductive vias, the disclosure is not limited to the embodiments. In other embodiments, the number of the conductive vias in each circuit substrate may be any integer more than one, such as one conductive via or three conductive vias.

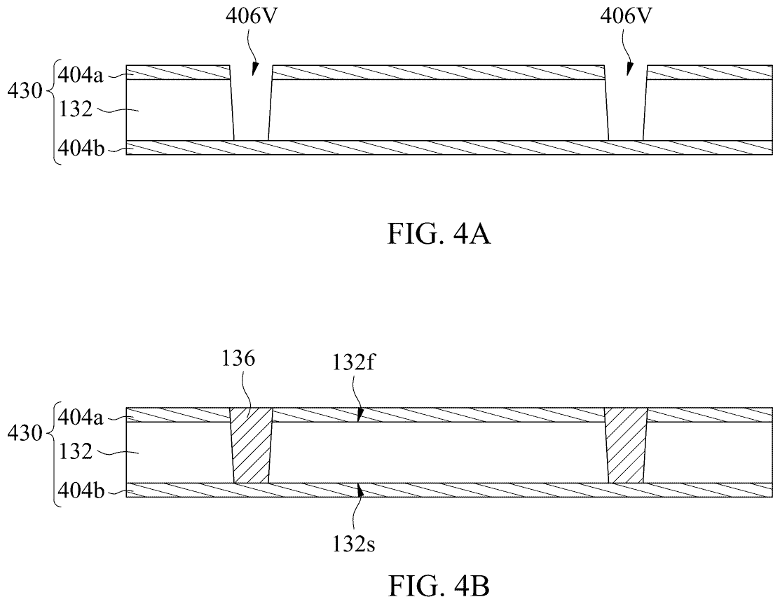

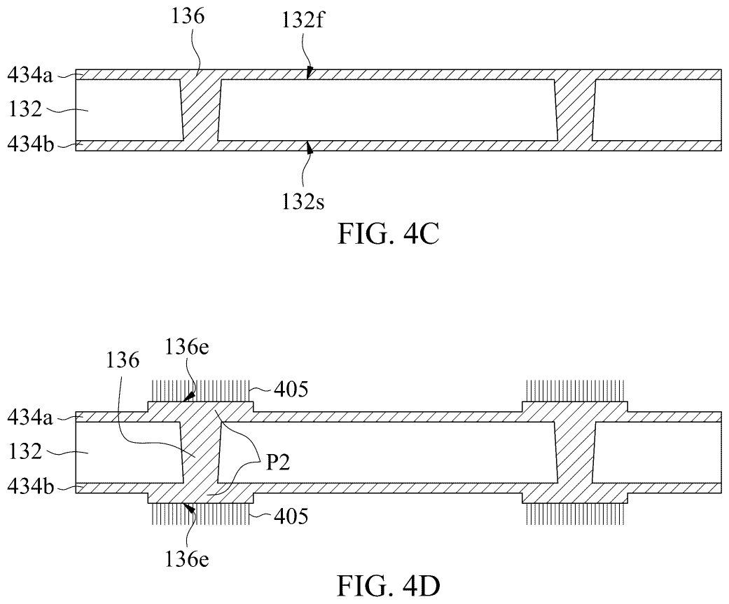

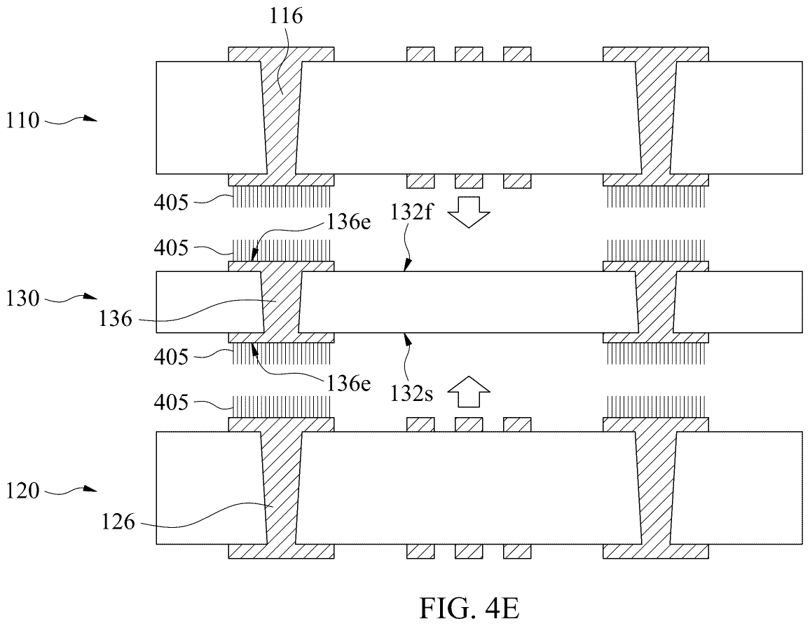

A method of manufacturing the circuit board includes sequent steps illustrated in FIG. 4A to FIG. 4E, while the method is in accordance with the circuit board 100. Firstly, at least two circuit substrates are formed. In the embodiment, three circuit substrates are formed (i.e., the circuit substrate 110, the circuit substrate 120 and the circuit substrate 130). Each of the circuit substrates includes an insulation substrate and a conductive via. The conductive via is disposed inside the insulation substrate, while the conductive via is connected to two opposite sides of the insulation substrate. For instance the circuit substrate 130 includes an insulation substrate 132 and the conductive via 136 disposed inside the insulation substrate 132, and the conductive via 136 is connected to two opposite sides of the insulation substrate 132 (as shown in FIG. 1).

Take the circuit substrate 130 as an example, the method of forming the circuit substrate 130 includes the following steps. Referring to FIG. 4A, firstly, an initial circuit substrate 430 is provided, and the initial circuit substrate 430 may be a copper clad laminate (CCL). The initial circuit substrate 430 includes the insulation substrate 132 and a metal layer 404a and a metal layer 404b which are located at two opposite sides of the insulation substrate 132. The insulation substrate 132 may be made of polymers, such as resins, while the metal layer 404a and the metal layer 404b may be deposited on the insulation substrate 132. In addition, materials of the metal layer 404a and the metal layer 404b may include copper.

Next, the metal layer 404a and the insulation substrate 132 may be laser-drilled so as to form a plurality of vias 406V on the initial circuit substrate 430 as shown in FIG. 4A. Referring to FIG. 4A and FIG. 4B, the metal materials, such as copper, may be deposited on the inner walls of the vias 406V by electroplating after the vias 406V are formed. Thus, a part of the conductive via 136 is formed. This part of the conductive via 136 is located between the metal layer 404a and the metal layer 404b and is electrically connected to the metal layer 404a and the metal layer 404b.

Referring to FIG. 4B and FIG. 4C, a part of the metal layer 404a, the metal layer 404b and the conductive via 136 may be removed by chemical mechanical polishing (CMP) after the part of the conductive via 136 is formed, so that a surface 132f and a surface 132s of the insulation substrate 132 are exposed. Next, a seed layer 434a and a seed layer 434b are deposited on the surface 132f and the surface 132s of the insulation substrate 132 separately by sputtering or electroplating. The material of the seed layer 434a and the seed layer 434b may include conductive materials, such as titanium or copper. The insulation substrate 132 is located between the seed layer 434a and the seed layer 434b, and the seed layer 434a is electrically connected to the seed layer 434b through a part of the conductive via 136.

Referring to FIG. 4D, a plurality of nanowires 405 are formed on at least one end surface 136e of the conductive via 136 by electroplating after the seed layer 434a and the seed layer 434b are deposited. Specifically, this step includes depositing each pad P2 on the seed layer 434a and the seed layer 434b separately so as to form the conductive via 136. Next, the plurality of nanowires 405 are formed on the end surface 136e of the conductive via 136 by electroplating, while the nanowires 405 extend to the direction away from the end surface 136e.

It is worth mentioning, in the embodiment, since the steps for forming the circuit substrate 110 and the circuit substrate 120 are similar to the steps for forming the circuit substrate 130, the descriptions of similar steps are not repeated hereof. The difference is that the nanowires 405 are disposed on both opposite sides of the circuit substrate 130, while the nanowires 405 are barely disposed on one side of the circuit substrate 110 and the circuit substrate 120. However, when the insulation substrate, e.g., the insulation substrate 132, is a glass substrate, an adhesion promotion layer (APL), such as oxides or nitrides, may be deposited on the surface 132f and the surface 132s of the insulation substrate 132 and on the inner walls of the vias 406V so as to enhance the bonding strength between the glass substrate and the metals.

For instance, the oxides included in the adhesion promotion layer may be titanium oxides, silicon dioxides or aluminum oxides, while the nitrides included in the adhesion promotion layer may be silicon nitrides. Further, the thickness of the adhesion promotion layer is between 0.01 nm and 100 nm.

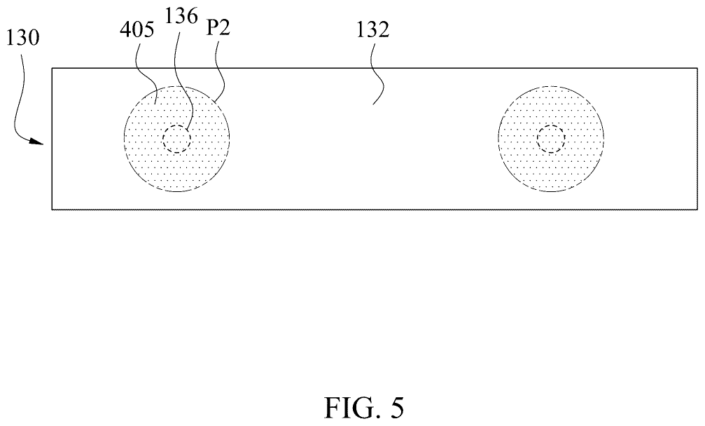

Referring to FIG. 4E and FIG. 5, the seed layer 434a and the seed layer 434b (shown in FIG. 4D) may be removed or patterned by lithography and etching after the nanowires 405 are formed. Thus, a part of the surface 132f and the surface 132s of the insulation substrate 132 are exposed. FIG. 5 illustrates a locally top view of the circuit substrate 130. The seed layer 434a and the seed layer 434b of the circuit substrate 130 in FIG. 5 are removed, and the nanowires 405 have been disposed on the conductive via 136 of the circuit substrate 130. Although the distribution area of the nanowires 405 in FIG. 5 is circular, the disclosure is not limited to the embodiment. The distribution area of the nanowires 405 may depend on the shape of the pads P2, that is, the distribution area of the nanowires 405 may be square, triangular or other shapes.

Next, as shown in FIG. 4E, the circuit substrate 110, the circuit substrate 120 and the circuit substrate 130 are laminated by heating and pressuring. During the laminating process, the nanowires 405 on the conductive via 136 are aligned to the conductive via 116 (and the conductive via 126). The nanowires 405 are located between the conductive via 116 and the conductive via 126. Specifically, the nanowires 405 disposed on one end surface 136e of the conductive via 136 are located between the conductive via 136 and the conductive via 116, while the nanowires 405 disposed on another end surface 136e of the conductive via 136 are located between the conductive via 136 and the conductive via 126.

In addition, the nanowires 405 disposed on the conductive via 116 of the circuit substrate 110 and the nanowires 405 disposed on the conductive via 126 of the circuit substrate 120 are located between the conductive via 116 and the conductive via 126. In other words, the nanowires 405 located at the circuit substrate 110 and the nanowires 405 located at the circuit substrate 120 are face-to-face.

As a result, the conductive layer 150 and the conductive layer 160 are formed from the nanowires 405 after those nanowires 405 are aligned to and laminated to one another. Specifically, the nanowires 405 are extruded and deformed, while the conductive layer (e.g., the conductive layer 150) which is extruded and deformed from the nanowires 405 may include the nanoporous structure. The metal atoms (e.g., copper atoms) of one nanowire 405 may diffuse to another nanowire 405 which is aligned to the aforementioned nanowire 405 or the conductive via 116 (and the conductive via 126) under heating and pressuring, so that the metal bonds are formed. Thus, the conductive via 116, the conductive via 126 and the conductive via 136 are electrically connected to one another through the conductive layer 150 and the conductive layer 160.

For instance, in the embodiment of FIG. 4E, the conductive layer 150 between the conductive via 136 and the conductive via 116 is formed after the nanowires 405 on one side of the circuit substrate 130 and the nanowires 405 on the circuit substrate 110 are aligned to and extruded to each other. In addition, the conductive layer 160 between the conductive via 136 and the conductive via 126 is formed after the nanowires 405 on the other side of the circuit substrate 130 and the nanowires 405 on the circuit substrate 120 are aligned to and extruded to each other.

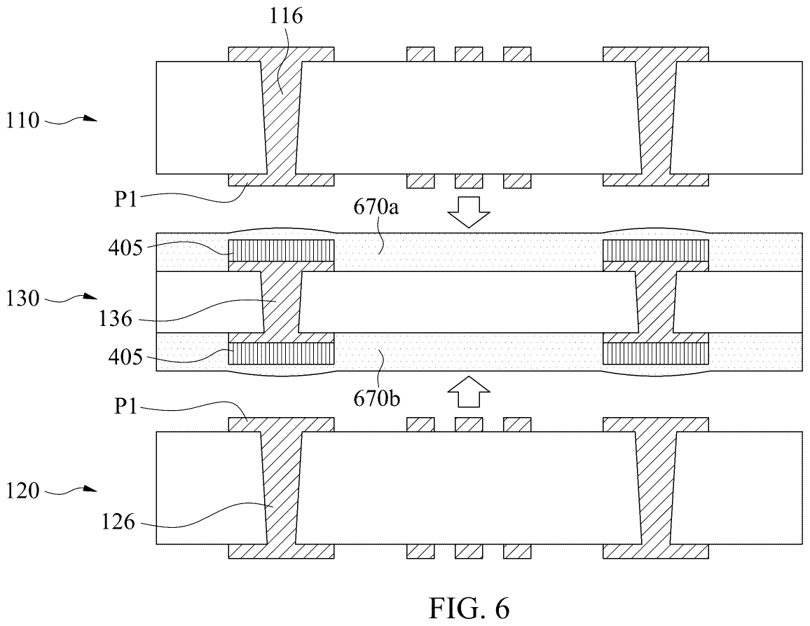

However, in another embodiment of FIG. 6, the nanowires 405 on one side of the circuit substrate 130 are aligned to the conductive via 116 of the circuit substrate 110 and directly touch the conductive via 116 after the laminating process. The nanowires 405 on the other side of the circuit substrate 130 are aligned to the conductive via 126 of the circuit substrate 120 and directly touch the conductive via 126 after the laminating process.

Referring to FIG. 1 and FIG. 4E, the method of manufacturing the circuit board further includes forming the insulation layer 170a on the circuit substrate 110 after the circuit substrate 110 and the circuit substrate 130 are laminated. The insulation layer 170a is located between the circuit substrate 110 and the circuit substrate 130 and surrounds the perimeter of the conductive layer 150. In addition, the step further includes forming the insulation layer 170b on the circuit substrate 120. The insulation layer 170b is located between the circuit substrate 120 and the circuit substrate 130 and surrounds the perimeter of the conductive layer 160.

It is worth mentioning, the method of forming the insulation layer 170a and the insulation layer 170b may include filling the spacing between the circuit substrate 110, the circuit substrate 120 and the circuit substrate 130 with insulation materials (not shown) and then curing the insulation materials by baking, drying or UV curing, so that the insulation layer 170a and the insulation layer 170b are formed.

Referring to FIG. 6, in the embodiment, the method of manufacturing the circuit board further includes disposing an insulation material 670a on the nanowires 405 located at one side (top side) of the circuit substrate 130 before the circuit substrate 110 and the circuit substrate 130 are laminated. The insulation material 670a covers the end surface 136e of the conductive via 136, while the insulation material 670a encapsulates the nanowires 405. In addition, the step further includes disposing an insulation material 670b on the nanowires 405 located at the other side (bottom side) of the circuit substrate 130. The insulation material 670b covers the other end surface 136e of the conductive via 136, while the insulation material 670b encapsulates the nanowires 405.

Next, the conductive via 116 and the conductive via 126 are adhered to the nanowires 405, so that the conductive via 116 and the conductive via 126 directly touch the nanowires 405. Specifically, since the insulation material 670a and the insulation material 670b are under a fluid state before cured by baking, drying or UV curing, the insulation material 670a flows over other regions when the end surface (not denoted) on the conductive via 116 of the circuit substrate 110 and the end surface (not denoted) on the conductive via 126 of the circuit substrate 120 touch the insulation material 670a and the insulation material 670b covering the nanowires 405. Thus, the conductive via 116 and the conductive via 126 directly touch the nanowires 405.

The insulation material 670a and the insulation material 670b may be cured by baking, drying or UV curing so as to form the insulation layer 170a and the insulation layer 170b in FIG. 1 after the conductive via 116 and the conductive via 126 directly touch the nanowires 405. Consequently, the circuit board 100 of FIG. 1 has been approximately completed.

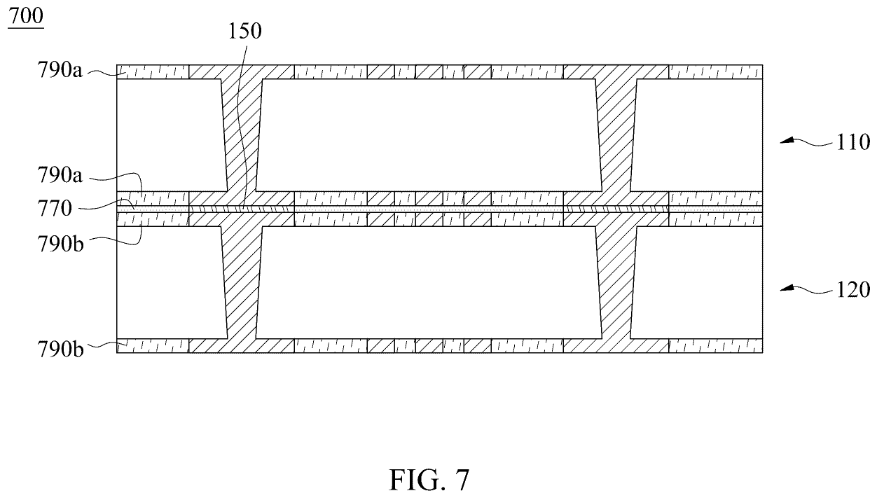

Referring to a circuit board 700 of another embodiment in FIG. 7, the circuit board 700 is similar to the circuit board 200. That is, the circuit board 700 includes the circuit substrate 110, the circuit substrate 120 and the conductive layer 150. The difference between the circuit board 700 and the circuit board 200 is that the circuit board 700 further includes two photoresist materials 790a and two photoresist materials 790b. The photoresist materials 790a are located at two opposite sides of the circuit substrate 110 separately, while the photoresist materials 790b are located at two opposite sides of the circuit substrate 120. An insulation layer 770 between the photoresist materials 790a and the photoresist materials 790b surrounds the conductive layer 150. In other embodiments, there may be the photoresist materials 790a and the insulation layer 770 disposed between the circuit substrate 110 and the circuit substrate 120 barely. It is worth mentioning, the photoresist materials 790a and the photoresist materials 790b of the circuit board 700 may be formed from those residual photoresists during at least one of the aforementioned steps, such as lithography process.

In conclusion, the nanowires are disposed on the laminating interfaces between circuit substrates so as to form the conductive layer including the nanoporous structure between the conductive vias which are connected to one another. As a result, the bonding strength between conductive vias of each circuit substrate may increase without affecting the electrical connections, so that the reliability of the circuit board increases. Therefore, when the insulation substrates of the circuit board are glass substrates, the aspect ratio of the conductive vias in the glass substrates may be increased by stacking multiple layers of the circuit substrates, thereby expanding the applications of the circuit board.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A circuit board, comprising:
two first circuit substrates stacked on each other, and each of the first circuit substrates comprises:
an insulation substrate;
a first conductive via disposed inside the insulation substrate, and the first conductive via is connected to two opposite sides of the insulation substrate; and
a first conductive layer disposed between the first conductive vias, and the first conductive vias are electrically connected to each other through the first conductive layer, and the first conductive layer comprises a nanoporous structure.

2. The circuit board of claim 1, further comprising:
an insulation layer disposed between the first circuit substrates and surrounding a perimeter of the first conductive layer.

3. The circuit board of claim 1, further comprising:
a conductive pillar disposed on the first conductive layer and located between one of the first conductive vias and the first conductive layer, wherein the one of the first conductive vias is electrically connected to the first conductive layer through the conductive pillar.

4. The circuit board of claim 1, wherein each of the first conductive vias comprises:
two pads disposed on two opposite end surfaces of the first conductive via, wherein the first conductive via is connected to the first conductive layer through one of the pads.

5. The circuit board of claim 1, wherein at least one of the insulation substrates is a glass substrate.

6. The circuit board of claim 1, further comprising:
a second circuit substrate disposed between the first circuit substrates, and the second circuit substrate is located between one of the first circuit substrates and first conductive layer, wherein the second circuit substrate comprises:
a second conductive via connected to two opposite sides of the second circuit substrate and electrically connected to the first circuit substrates, and the second conductive via is connected to one of the first conductive vias through the first conductive layer; and
a second conductive layer disposed on the second conductive via, wherein the second circuit substrate is located between the first conductive layer and the second conductive layer, and the second conductive via is connected to another one of the first conductive vias through the second conductive layer, wherein the second conductive layer comprises the nanoporous structure.

7. The circuit board of claim 1, wherein a ratio of a thickness of the insulation substrate to a width of the first conductive via is between 1 and 20.

8. The circuit board of claim 1, wherein a thickness of the insulation substrate is between 50 μm and 4000 μm.

9. The circuit board of claim 1, wherein a width of the first conductive via is between 50 μm and 200 μm.

10. The circuit board of claim 1, wherein the nanoporous structure comprises a plurality of pores, and a diameter of the plurality of pores is between 1 nm and 10 μm.

11. A method of manufacturing a circuit board, comprising:
forming at least two circuit substrates, and each of the circuit substrates comprises:
an insulation substrate;
a conductive via disposed inside the insulation substrate, and the conducive via is connected to two opposite sides of the insulation substrate;
forming a plurality of nanowires on at least one end surface of one of the conductive vias, and the plurality of nanowires extend to a direction away from the at least one end surface; and
laminating the circuit substrates after the plurality of nanowires are formed, wherein the nanowires located at the one of the conductive vias are aligned to another one of the conductive vias, and the plurality of nanowires are located between the conductive vias, and a conductive layer is formed from the plurality of nanowires, wherein the conductive vias are electrically connected to each other through the conductive layer, and the conductive layer comprises a nanoporous structure.

12. The method of claim 11, further comprising:
forming an insulation layer on the circuit substrates after the circuit substrates are laminated, and the insulation layer is located between the circuit substrates, wherein the insulation layer surrounds a perimeter of the conductive layer.

13. The method of claim 11, further comprising:
disposing an insulation material on the plurality of nanowires before the circuit substrates are laminated, wherein the insulation material covers the end surface of the one of the conductive vias, and the insulation material encapsulates the plurality of nanowires; and
adhering another one of the conductive vias to the plurality of nanowires, and the another one of the conductive vias touches the plurality of nanowires directly.

14. The method of claim 11, wherein at least one of the insulation substrates is a glass substrate.

15. The method of claim 11, wherein the nanoporous structure includes a plurality of pores, and a diameter of the plurality of pores is between 1 nm and 10 μm.
